(19) United States
(12) Patent Application Publication
(10) Pub. No.: US 2026/0123009 A1
(43) Pub. Date: Apr. 30, 2026

(54) SEMICONDUCTOR DEVICE AND METHOD OF MANUFACTURING THE SAME

(71) Applicant: Samsung Electronics Co., Ltd., Suwon-si (KR)

(72) Inventors: Kyooho JUNG, Suwon-si (KR); Sangwook KIM, Suwon-si (KR); Jeeeun YANG, Suwon-si (KR)

(73) Assignee: Samsung Electronics Co., Ltd., Suwon-si (KR)

(21) Appl. No.: 19/074,639

(22) Filed: Mar. 10, 2025

(30) Foreign Application Priority Data
Oct. 29, 2024 (KR) 10-2024-0149928

(51) Int. Cl. H10D 64/23; H10D 30/01; H10D 30/63; H10D 62/17; H10D 62/80; H10D 64/62

(52) U.S. Cl. CPC H10D 64/258; H10D 30/025; H10D 30/63; H10D 62/292; H10D 62/875; H10D 64/252; H10D 64/62

(57) ABSTRACT

A semiconductor device may include a lower electrode, a channel on the lower electrode, a gate insulating layer on the channel, a gate electrode on the gate insulating layer, and an upper electrode on the gate electrode. The lower electrode may include a doped region. The doped region may include In or Nb. The upper electrode, the channel, and the lower electrode may be spaced apart from each other in a direction perpendicular to the lower electrode.

### CROSS-REFERENCE TO RELATED APPLICATION

This application is based on and claims priority under 35 U.S.C. § 119 to Korean Patent Application No. 10-2024-0149928, filed on Oct. 29, 2024, in the Korean Intellectual Property Office, the disclosure of which is incorporated by reference herein in its entirety.

### BACKGROUND

### 1. Field

The disclosure relates to a semiconductor device having a doped region formed in a lower electrode and/or a method of manufacturing the same.

### 2. Description of the Related Art

Transistors are semiconductor devices that perform electrical switching functions and are employed in various integrated circuit devices including memories, drive integrated circuits (ICs), and logic devices. In order to increase the degree of integration of integrated circuit devices, the space occupied by transistors is rapidly being reduced, and thus, research is being conducted to reduce the size of transistors while maintaining their performance.

A gate electrode is one of the important parts of a transistor. When a voltage is applied to a gate electrode, a channel adjacent to the gate may open a path for current, and in the opposite case, the current may be blocked. The performance of a semiconductor may depend on how much leakage current is reduced and efficiently managed between a gate electrode and a channel. The larger an area of contact between the gate electrode and the channel, which control current in a transistor, the higher the power efficiency.

As semiconductor processes become more sophisticated, the size of a transistor may decrease, and the area of contact between the gate electrode and the channel becomes smaller, which may cause problems due to a short channel effect. For example, there are phenomena such as threshold voltage variation, carrier velocity saturation, and deterioration of the subthreshold characteristics. Accordingly, methods are being sought to overcome the short channel effect and effectively reduce the channel length.

### SUMMARY

Provided is a semiconductor device having a doped region formed in a lower electrode and a method of manufacturing the same.

Additional aspects will be set forth in part in the description which follows and, in part, will be apparent from the description, or may be learned by practice of the presented embodiments of the disclosure.

According to an example embodiment of the disclosure, a semiconductor device may include a lower electrode, a channel on the lower electrode, a gate insulating layer on the channel, a gate electrode on the gate insulating layer, and an upper electrode on the gate electrode. The lower electrode may include a doped region, and the doped region may include In or Nb. The upper electrode, the channel, and the lower electrode may be spaced apart from each other in a direction perpendicular to the lower electrode.

According to an example embodiment of the disclosure, a method of manufacturing a semiconductor device includes forming an oxide layer on a lower electrode, forming a doped region in the lower electrode by heat-treating the oxide layer, wet-etching and removing the oxide layer, and forming a channel on the doped region. The oxide layer may include at least one of indium (In) and niobium (Nb), and the doped region may include at least one of In and Nb.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a diagram illustrating a semiconductor device according to an embodiment;

FIG. 2 is a diagram illustrating a semiconductor device including a buffer, according to another embodiment;

FIG. 3 is a diagram illustrating a semiconductor device including a buffer, according to another embodiment;

FIG. 4 is a flowchart illustrating a method of manufacturing a semiconductor device, according to an embodiment;

FIG. 5 to FIG. 15 are diagrams for explaining a method of manufacturing a semiconductor device, according to an embodiment;

FIG. 16 is a diagram illustrating a memory device including a semiconductor device according to an embodiment;

FIG. 17 is a schematic block diagram of a display driver IC (DDI) including a semiconductor device according to an embodiment and a display device having a DDI;

FIG. 18 is a circuit diagram of a CMOS inverter including a semiconductor device according to an embodiment;

FIG. 19 is a circuit diagram of a CMOS SRAM device including a semiconductor device according to an embodiment;

FIG. 20 is a circuit diagram of a CMOS NAND circuit including a semiconductor device according to an embodiment;

FIG. 21 is a block diagram of an electronic system including a semiconductor device according to an embodiment; and

FIG. 22 is a block diagram of an electronic system including a semiconductor device according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C” and “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

The notion that elements are “substantially the same” may indicate that the element may be completely the same and may also indicate that the elements may be determined to be the same in consideration of errors or deviations occurring during a process.

Hereafter, embodiments will be described more fully with reference to the accompanying drawings. In the drawings, like reference numerals refer to like elements, and in the drawings, sizes of constituent elements may be exaggerated for clarity and convenience of explanation. Although the terms ‘first’, ‘second’, etc. may be used herein to describe various constituent elements, these constituent elements should not be limited by these terms. These terms are only used to distinguish one constituent element from another.

Singular forms include the plural forms unless the context clearly indicates otherwise. When a part “comprises” or “includes” an element in the specification, unless otherwise defined, it is not excluding other elements but may further include other elements. In the drawings, sizes or thicknesses of constituent elements may be exaggerated for clarity of descriptions.

The term “above” and similar directional terms may be applied to both singular and plural.

With respect to operations that constitute a method, the operations may be performed in any appropriate sequence unless the sequence of operations is clearly described or unless the context clearly indicates otherwise. All example terms (for example, etc.) are simply used to explain in detail the technical scope of the present disclosure, and thus, the scope of the present disclosure is not limited by the examples or the example terms as long as it is not defined by the claims.

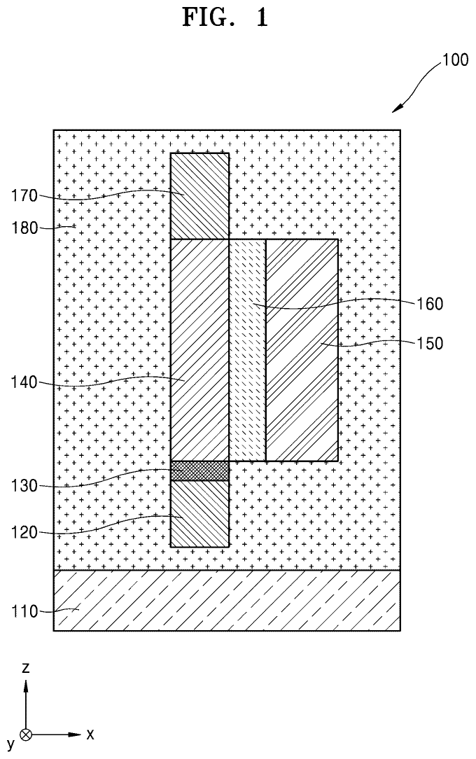

FIG. 1 is a diagram illustrating a semiconductor device 100 according to an embodiment.

Referring to FIG. 1, the semiconductor device 100 may include a lower electrode 120, a doped region 130, a channel 140, a gate electrode 150, a gate insulating layer 160, an upper electrode 170, and/or a mold insulating material 180. The lower electrode 120 may include a metal material. The lower electrode (120) may include at least one selected from the group consisting of tungsten (W), cobalt (Co), nickel (Ni), iron (Fe), Ti titanium (Ti), molybdenum (Mo), chromium (Cr), zirconium (Zr), hafnium (Hf), niobium (Nb), tantalum (Ta), silver (Ag), gold (Au), aluminum (AI), copper (Cu), antimony (Sb), vanadium (V), ruthenium (Ru), platinum (Pt), zinc (Zn), and magnesium (Mg). The lower electrode 120 may include the doped region 130.

The doped region 130 may be provided on a part of the lower electrode 120. The doped region 130 may be provided on an upper portion of the lower electrode 120. The doped region 130 may be provided in a region adjacent to the oxide channel 140 in the lower electrode 120. The doped region 130 may be closer to the oxide channel 140 compared to a part of the lower electrode 120 that does not include the doped region 130. The doped region 130 may be provided from an upper surface of the lower electrode 120 to a region having a certain height therefrom in a direction perpendicular to the lower electrode 120 (Z direction). The doped region 130 may be provided from a first end where the oxide channel 140 contacts the mold insulating material 180 to a second end in a direction parallel to the lower electrode 120 (for example, X direction). The doped region 130 may include at least one of indium (In) and Nb. The doped region 130 may include In, and the lower electrode 120 may include W. Or the doped region 130 may include Nb, and the lower electrode 120 may include Ti. The atomic percentage of at least one of In and Nb in the doped region 130 may be approximately 10 at % (atomic percent) or more and 30 at % or less. In the doped region 130, the atomic percentage of at least one of In and Nb may be higher in a portion adjacent to the oxide channel 140 than in a portion adjacent to a lower portion of the lower electrode 120.

The oxide channel 140 may be provided in the lower electrode 130. For example, the oxide channel 140 may be provided on the doped region 130 of the lower electrode 120. The oxide channel 140 may be provided in a direction perpendicular to the lower electrode 120 (Z direction). The oxide channel 140 may be in contact with an upper surface of the doped region 130. The oxide channel 140 may be deposited using an ALD method. The oxide channel 140 may be deposited using a plasma enhanced-atomic layer deposition (PE-ALD) method. The oxide channel 140 may be selected from the group consisting of InGaZnO, ZnO, ZrInZnO, InZnO, InGaZnO₄, ZnSnO, In₂O₃, Ga₂O₃, HfInZnO, GaInZnO, HfO₂, SnO₂, WO₃, TiO₂, Ta₂O₅, In₂O₃SnO₂, MgZnO, ZnSnO₃, ZnSnO₄, CdZnO, CuAlO₂, CuGaO₂, Nb₂O₅, TiSrO₃, zinc indium oxide (ZIO), indium gallium oxide (IGO), and any combination thereof. The oxide channel 140 may function as a channel layer and have a band gap of 3.0 eV or more. The oxide channel 140 may be in contact with the mold insulating material 180 at the first and second ends in a direction parallel to the lower electrode 120 (X direction).

The gate electrode 150 may be arranged to be spaced apart from the oxide channel 140. The gate electrode 150 may be arranged to face a part or all of the oxide channel 140. The gate electrode 150 may include an electrically conductive material. For example, the gate electrode 150 may include a metal or a metal compound. At this time, the gate insulating layer 160 may be arranged between the oxide channel 140 and the gate electrode 150 to electrically disconnect the oxide channel 140 and the gate electrode 150. The gate insulating layer 160 may include an insulating material. For example, the gate insulating layer 160 may include a dielectric. A width of the gate insulating layer 160 may be the same as a width of the gate electrode 150.

The upper electrode 170 may be arranged on the oxide channel 140. The upper electrode 170 may include a metal material. The upper electrode 170 may be positioned on the oxide channel 140 in a direction in which the lower electrode 120, the doped region 130, and the oxide channel 140 are sequentially stacked. The upper electrode 170 may be positioned in the vertical direction on the oxide channel 140. The lower electrode 120, the doped region 130, the oxide channel 140, and the upper electrode 170 may be sequentially stacked in a direction perpendicular to the substrate 110 without the intervention of other layers.

The mold insulating material 180 may fill an empty space so that the lower electrode 120, the doped region 130, the oxide channel 140, the upper electrode 170, the gate electrode 150, and the gate insulating layer 160 are fixed on the substrate 110. The mold insulating material 180 may include an insulating material. The mold insulating material 180 may include, for example, silicon nitride (SiN).

The channel 140, the gate electrode 150, and/or the gate insulating layer 160 may be arranged vertically to the substrate 110, and the semiconductor device 100 may have a 3D structure (e.g., a vertical channel structure). A longitudinal direction of the channel 140 may be arranged vertically to the substrate 110.

The semiconductor device 100 according to an embodiment may provide a semiconductor device with improved electrical characteristics such as Subthreshold Swing (SS), Ion, Ioff, and Ion/off ratio by forming the doped region 130 in the lower electrode 120 in the semiconductor device having a vertical channel structure and providing the channel 140 on the doped region 130.

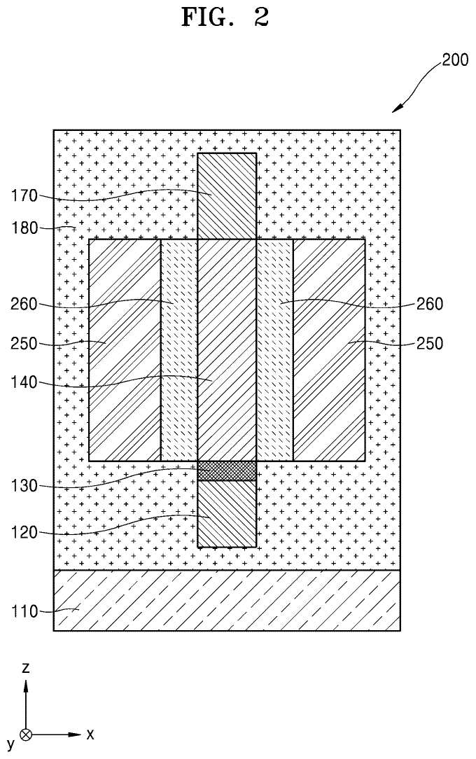

FIG. 2 is a drawing illustrating a semiconductor device 200 including a buffer according to another embodiment. In FIG. 2, components using the same reference numbers as those in FIG. 1 have substantially the same configuration and operational effects as those described with reference to FIG. 1, and therefore, detailed descriptions thereof are omitted.

Referring to FIG. 2, the semiconductor device 200 includes a lower electrode 120, a doped region 130, a channel 140, and an upper electrode 170 arranged in a direction perpendicular to a substrate 110 (z direction). A gate insulating layer 260 may be provided around the channel 140, and a gate electrode 250 may be provided around the gate insulating layer 260. The gate electrode 250 may be provided around the channel 140 to increase an area where the gate electrode 250 and the channel 140 face each other and improve the short channel effect.

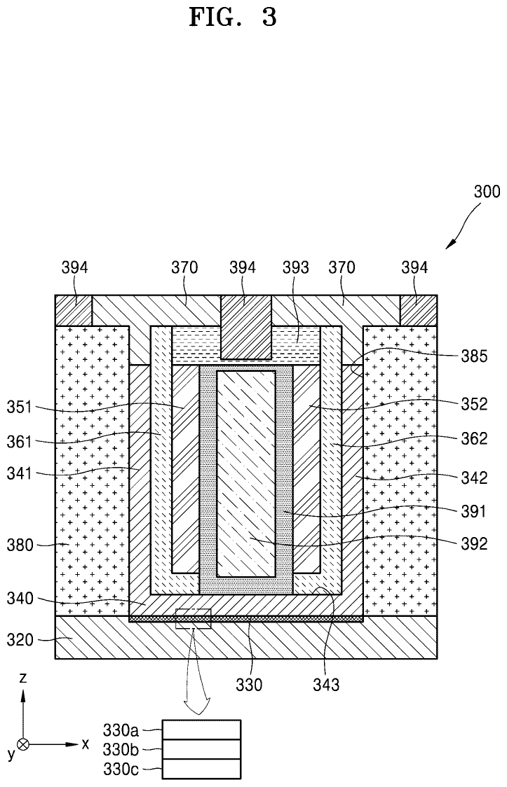

FIG. 3 is a drawing illustrating a semiconductor device 300 according to another embodiment.

Referring to FIG. 3, the semiconductor device 300 may include a lower electrode 320, a channel 340 provided in the lower electrode 320, and an upper electrode 370 provided in the channel 340. The lower electrode 320 may be a source electrode, and the upper electrode 370 may be a drain electrode, alternatively, the lower electrode 320 may be a drain electrode, and the upper electrode 370 may be a source electrode.

The lower electrode 320 may include a metal material. The lower electrode 320 may include at least one selected from the group consisting of W, Co, Ni, Fe, Ti, Mo, Cr, Zr, Hf, Nb, Ta, Ag, Au, Al, Cu, Sb, V, Ru, Pt, Zn, and Mg. The lower electrode 320 may include W or Ti. The lower electrode 320 may include a doped region 330.

The doped region 330 may be provided on a part of the lower electrode 320. The doped region 330 may be provided on an upper portion of the lower electrode 320. The doped region 330 may be provided in a region adjacent to the channel 340 in the lower electrode 320. The doped region 330 may be provided in a direction perpendicular to the lower electrode 320 (Z direction) to an upper surface of the lower electrode 320 and a region having a certain height therefrom. In addition, the doped region 330 may be provided from a first end where a mold insulating material 380 contacts a first vertical extension portion 341 of the channel 340 in a direction parallel to the lower electrode 320 (for example, in the X direction) to a second end where the mold insulating material 380 contacts a second vertical extension portion 342 of the channel 340. The doped region 330 may be provided to cover a lower end 343 of the channel 340. The doped region 330 may include, for example, In or Nb. The doped region 330 may include In, and the lower electrode 320 may include W. Alternatively, the doped region 330 may include Nb, and the lower electrode 320 may include Ti. The atomic percentage of at least one of In and Nb in the doped region 330 may be 10 at % or more and 30 at % or less. The atomic percentage of at least one of In and Nb in the doped region 330 may be higher in a portion adjacent to the channel 340 than in a portion adjacent to a lower portion of the lower electrode 320. For example, the doped region 330 may include a first doped region 330a, a second doped region 330b, and a third doped region 330c. The second doped region 330b may be between the first doped region 330a and the third doped region 330c. The first doped region 330a may be adjacent to the channel 340. The third doped region 330c may be adjacent to the lower electrode 320. The atomic percentage of at least one of In and Nb in the first doped region 330a may be higher than the atomic percentage of at least one of In and Nb in the third doped region 330c. The atomic percentage of at least one of In and Nb in the second doped region 330b may less than the atomic percentage of at least one of In and Nb in the first doped region 330a and greater than the atomic percentage of at least one of In and Nb in the third doped region 330c.

The mold insulating material 380 may be provided on the lower electrode 320 to cover a portion of a surface of the lower electrode 320. The channel 340 may be provided on a side of the mold insulating material 380. The mold insulating material 380 may be provided on one side of the first vertical extension portion 341 of the channel 340, and the mold insulating material 380 may be provided on one side of the second vertical extension portion 342 of the channel 340. The mold insulating material 380, the first vertical extension portion 341 of the channel 340, the second vertical extension portion 342 of the channel 340, and the mold insulating material 380 may be sequentially provided in a direction parallel to the lower electrode 320 (e.g., X direction). The mold insulating material 380 may include an insulating material. The mold insulating material 380 may include, for example, silicon nitride (SiN). The mold insulating material 380 may contact a side of the channel 340 and surround channel 340. The channel 340 may be provided in an opening 385 defined by the mold insulating material 380.

The channel 340 may be provided on the lower electrode 320. For example, the channel 340 may be provided on the doped region 330 of the lower electrode 320. The channel 340 may have a U-shaped cross-sectional shape. The channel 340 may include a lower portion 343 that contacts the lower electrode 320, the first vertical extension portion 341 that extends from one end of the lower portion 343 in a direction perpendicular to the lower electrode 320 (Z direction), and the second vertical extension portion 342 that extends from the other end of the lower portion 343 in a direction perpendicular to the lower electrode 320 (Z direction). The channel 340 may be in contact with an upper surface of the doped region 330. The channel 340 may be deposited by an ALD method. The channel 340 may be deposited by a plasma enhanced-atomic layer deposition (PE-ALD) method. The channel (340) may be selected from the group consisting of InGaZnO, ZnO, ZrInZnO, InZnO, InGaZnO₄, ZnSnO, In₂O₃, Ga₂O₃, HfInZnO, GaInZnO, HfO₂, SnO₂, WO₃, TiO₂, Ta₂O₅, In₂O₃SnO₂, MgZnO, ZnSnO₃, ZnSnO₄, CdZnO, CuAlO₂, CuGaO₂, Nb₂O₅, TiSrO₃, ZIO, IGO, and any combination thereof.

A first gate electrode 351 may be arranged spaced apart from the first vertical extension portion 341, and a second gate electrode 352 may be arranged spaced apart from the second vertical extension portion 342. A first gate insulating layer 361 may be provided between the first vertical extension portion 341 and the first gate electrode 351, and a second gate insulating layer 362 may be provided between the second vertical extension portion 342 and the second gate electrode 352.

The first gate electrode 351 and/or the second gate electrode 352 may extend in a second horizontal direction (Y direction). The first gate electrode 351 and the second gate electrode 352 may be positioned spaced apart from each other. The first gate electrode 351 and/or the second gate electrode 352 may include an electrically conductive material. For example, the first gate electrode 351 and/or the second gate electrode 352 may include a metal or a metal compound. The first gate electrode 351 and/or the second gate electrode 352 may form a word line. An electrical signal input to the first gate electrode 351 may not match an electrical signal input to the second gate electrode 352. The first gate electrode 351 may control a channel of the first vertical extension portion 341 and the second gate electrode 352 may control a channel of the second vertical extension portion 342.

An insulating liner 391 may be disposed between the first gate electrode 351 and the second gate electrode 352 that are spaced apart from each other. The insulating liner 391 may be conformally disposed on opposing sidewalls of the first gate electrode 351 and the second gate electrode 352 and/or an upper surface of the channel 340. The insulating liner 391 may have an upper surface arranged in the same plane as upper surfaces of the first gate electrode 351 and the second gate electrode 352. The insulating liner 391 may include, for example, silicon nitride. A buried insulating layer 392 may fill a space between the first gate electrode 351 and the second gate electrode 352 that are spaced apart from each other on the insulating liner 391. The buried insulating layer 392 may include, for example, silicon oxide. An upper insulating layer 393 may be disposed on the upper surfaces of the first gate electrode 351, the second gate electrode 352, and/or the buried insulating layer 392. The upper surface of the upper insulating layer 393 may be arranged at the same level as an upper surface of the mold insulating material 380.

The upper electrode 370 may be arranged at the upper surface of the channel 340. The upper electrode 370 may function as a landing pad. The upper electrode 370 may include an upper left electrode and an upper right electrode. The upper right electrode may be electrically connected to the first vertical extension portion 341. The upper left electrode may be electrically connected to the second vertical extension portion 342. The upper right electrode and the upper left electrode may not be electrically connected. The upper electrode 370 may include an upper portion and a lower portion having different widths. The upper portion of the upper electrode 370 may be arranged at a level higher than the upper surface of the mold insulating material 380. The lower portion of the upper electrode 370 may be placed inside a recess defined between the mold insulating material 380 and the upper insulating layer 393. In one embodiment, the upper portion of the upper electrode 370 may have a first width in the first horizontal direction (X direction), and the lower portion of the upper electrode 370 may have a second width less than the first width in the first horizontal direction (X direction). The lower portion of the upper electrode 370 may be placed inside the recess, and the upper portion of the upper electrode 370 may have a bottom surface that is placed on the upper surface of the mold insulating material 380 and the upper insulating layer 393 on the lower portion of the upper electrode 370, and accordingly, the upper electrode 370 may have a vertical cross-section of a T shape. A bottom surface of the lower portion of the upper electrode 370 may be in contact with an upper surface of the first vertical extension portion 341 and/or the second vertical extension portion 342. Both sidewalls of the lower portion of the upper electrode 370 may be aligned with both sidewalls of the first vertical extension portion 341 and the second vertical extension portion 342. The bottom surface of the lower portion of the upper electrode 370 may be arranged at a level higher than the upper surface of the first gate electrode 351 and/or the second gate electrode 352, and a portion of the sidewalls of the lower portion of the upper electrode 370 may be covered by the first gate insulating layer 361 and/or the second gate insulating layer 362. An insulating layer 394 surrounding the upper electrode 370 may be arranged on the upper surface of the mold insulating material 380 and the upper insulating layer 393.

The semiconductor device 300 may have a vertical channel transistor (VCT) structure including the channel 340 having vertical portions extending in a vertical direction (Z direction) to the lower electrode 320. The first gate insulating layer 361 may have an L cross-sectional shape, and the second gate insulating layer 362 may have a cross-sectional shape symmetrical to the second gate insulating layer 361 based on the buried insulating layer 392. The first gate electrode 351 and the second gate electrode 352 may have a straight cross-sectional shape. Alternatively, the first gate insulating layer 362 and the second gate insulating layer 361 may have a straight cross-sectional shape like the first gate electrode 351 and the second gate electrode 352.

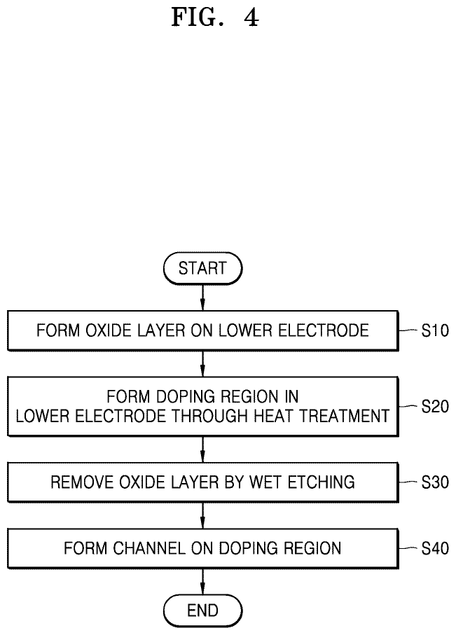

FIG. 4 is a flow chart illustrating a method of manufacturing a semiconductor device according to an embodiment.

Referring to FIG. 4, an oxide layer is formed on a lower electrode (S10). The oxide layer may be an indium oxide layer including In. Alternatively, the oxide layer may be a niobium oxide layer including Nb. After that, heat treatment may be performed so that In included in the indium oxide layer or Nb included in the niobium oxide layer is diffused into the lower electrode to form a doped region (S20). After forming the doped region on the lower electrode, the oxide layer may be etched (S30). At this time, only the oxide layer formed on the lower electrode may be selectively etched through wet etching. After etching the oxide layer, a channel may be formed on the doped region (S40). After forming the channel, a gate insulating layer may be deposited on the channel, a gate electrode may be deposited on the gate insulating layer, and an upper electrode may be mounted on the channel.

In FIGS. 1 to 3, a vertical structure transistor is shown as an example, but the method of manufacturing a semiconductor device described above may be applied to semiconductor devices of various structures, such as a planar structure semiconductor device.

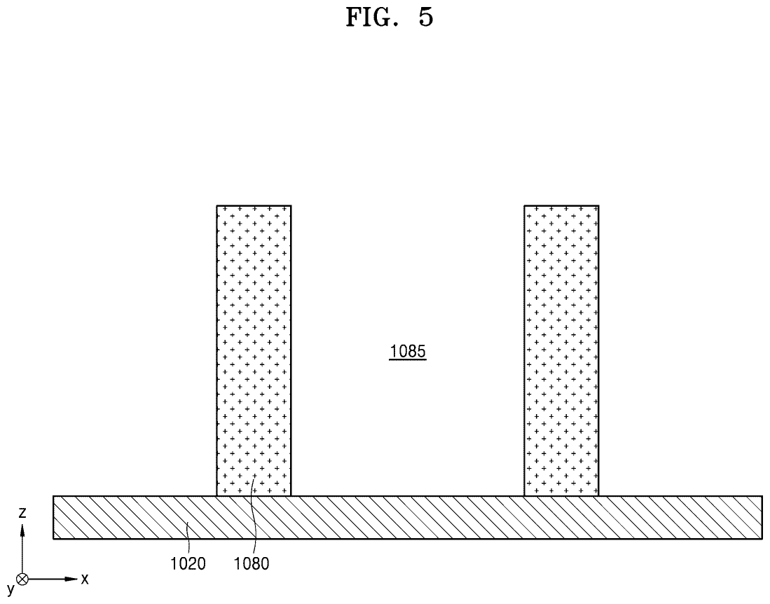

Next, a method of manufacturing a semiconductor device according to an embodiment will be described with reference to FIGS. 5 to 14.

Referring to FIG. 5, a plurality of mold insulating materials 1080 extending in the second horizontal direction (Y direction) may be deposited on a lower electrode 1020 extending in the first horizontal direction (X direction). The mold insulating material 1080 may be stacked until a desired and/or alternatively predetermined height is reached in the vertical direction (z direction). The plurality of mold insulating materials 1080 and the lower electrode 1020 may form an opening 1085.

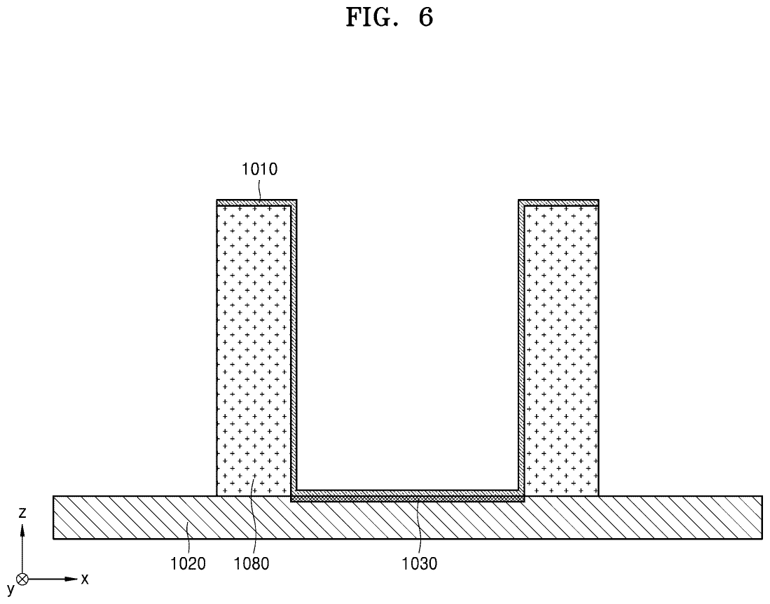

Referring to FIG. 6, an indium oxide layer 1010 may be deposited on the lower electrode 1020 and the mold insulating material 1080. The indium oxide layer 1010 may include indium oxide (InOx). After depositing the indium oxide layer 1010 on the lower electrode 1020 and the mold insulating material 1080, heat treatment may be performed so that a doped region 1030 is formed on the lower electrode 1020. At this time, the lower electrode 1020 includes W, and the mold insulating material 1080 includes SiN, and thus, even if an indium oxide layer 1010 is deposited on each of the lower electrode 1020 and the mold insulating material 1080 and heat treated, the doped region 1030 is not formed on the mold insulating material 1080, but the doped region 1030 may be formed only on the lower electrode 1020.

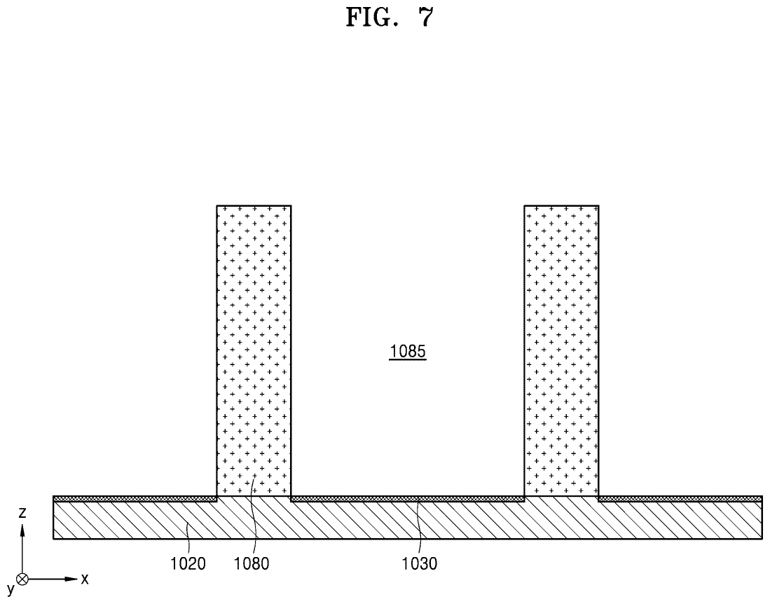

Referring to FIG. 7, the indium oxide layer 1010 deposited on the lower electrode 1020 and the mold insulating material 1080 may be removed through a wet etching process. At this time, the doped region 1030 formed on the lower electrode 1020 may not be removed through the wet etching. Alternatively, as described above, a niobium oxide layer including niobium oxide (NbOx) may be deposited on the lower electrode 1020 and the mold insulating material 1080 instead of the indium oxide layer 1010. At this time, the lower electrode 1020 may include Ti, and the mold insulating material may include SiN, so that the doped region 1030 is formed only on the lower electrode 1020.

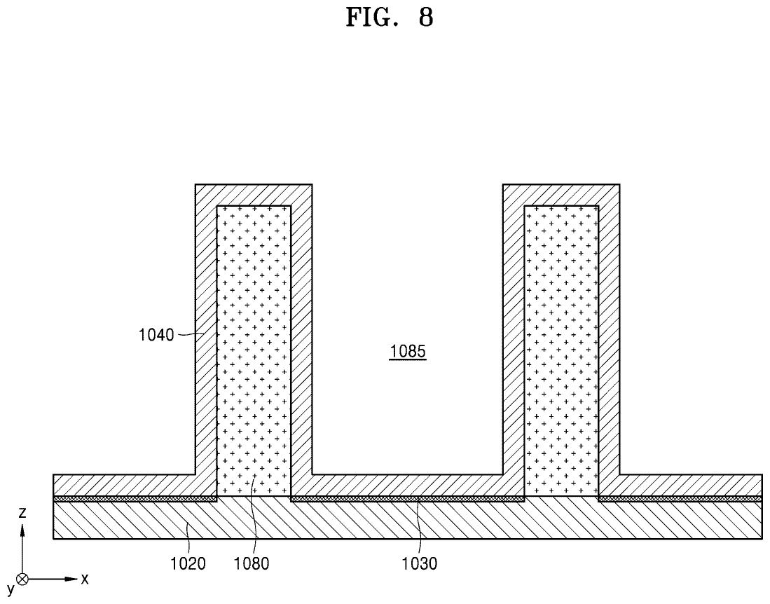

Referring to FIG. 8, a channel 1040 may be deposited on the mold insulating material 1080. The channel 1040 may be deposited by sputtering, thermal-ALD, or PE-ALD. The channel 1040 may have a U-shaped cross-sectional shape.

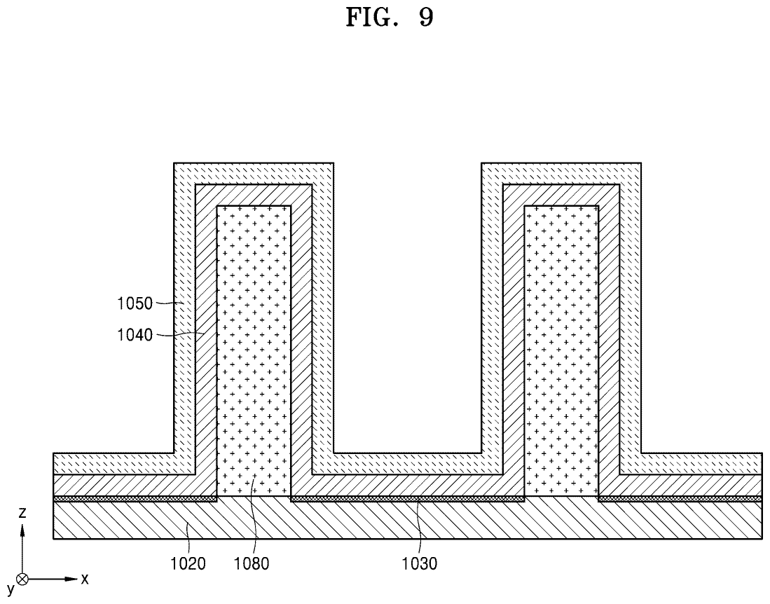

Referring to FIG. 9, a gate electrode 1050 may be stacked on a surface of the channel 1040.

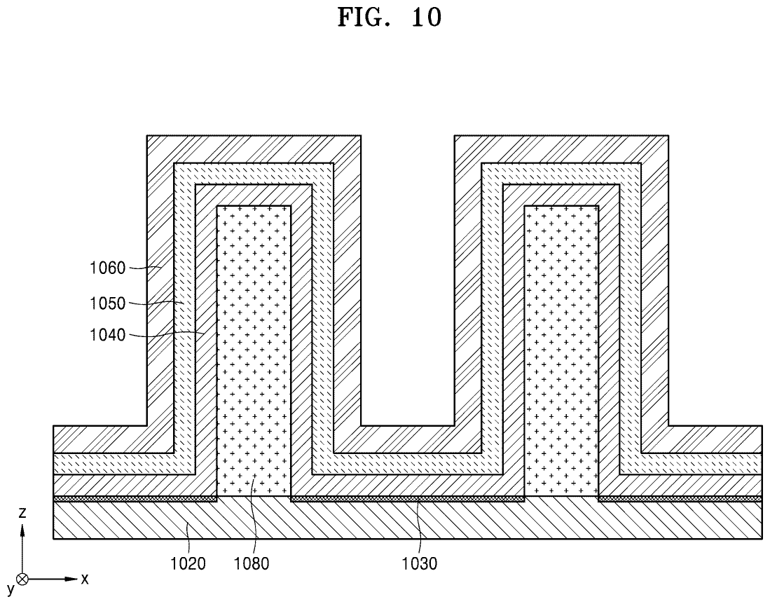

Referring to FIG. 10, a gate insulating layer 1060 may be stacked on a surface of the gate electrode 1050.

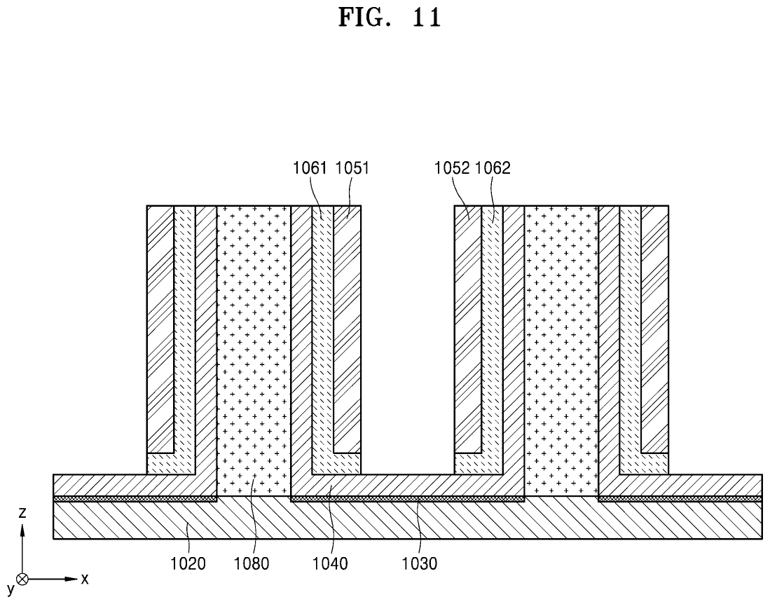

Referring to FIG. 11, anisotropic etching may be performed from an upper portion of the gate electrode 1050 of the structure illustrated in FIG. 8. The gate electrode 1050, the gate insulating layer 1060, and the channel 1040 may be etched in an upper direction of the mold insulating material 1080, and thus, an upper surface of the mold insulating material 1080 may be exposed. Thereby, the gate electrode 1050 may be separated into a first gate electrode 1051 and a second gate electrode 1052, and the gate insulating layer 1060 may be separated into a first gate insulating layer 1061 and a second gate insulating layer 1062. In addition, the gate electrode 1050, the gate insulating layer 1060, and the channel 1040 may be etched in the upper direction of the mold insulating material 1080, and thus, the upper surface of the mold insulating material 1080 may be exposed. Levels of the upper surface of the mold insulating material 1080, upper surfaces of the first gate electrode 1051 and the second gate electrode 1052, and upper surfaces of the first gate insulating layer 1061 and the second gate insulating layer 1062 may be identical. If the gate electrode 1050 is etched once more, the upper surface levels of the first gate insulating layer 1061 and the second gate insulating layer 1062 may be lower than the upper surface levels of the mold insulating material 1080, the first vertical extension portion 1041 and the second vertical extension portion 1042, and the first gate electrode 1051 and the second gate electrode 1052.

In addition, the gate electrode 1050 and the gate insulating layer 1060 may be etched toward a lower end direction of the opening to expose a portion of an upper surface of the channel 1040.

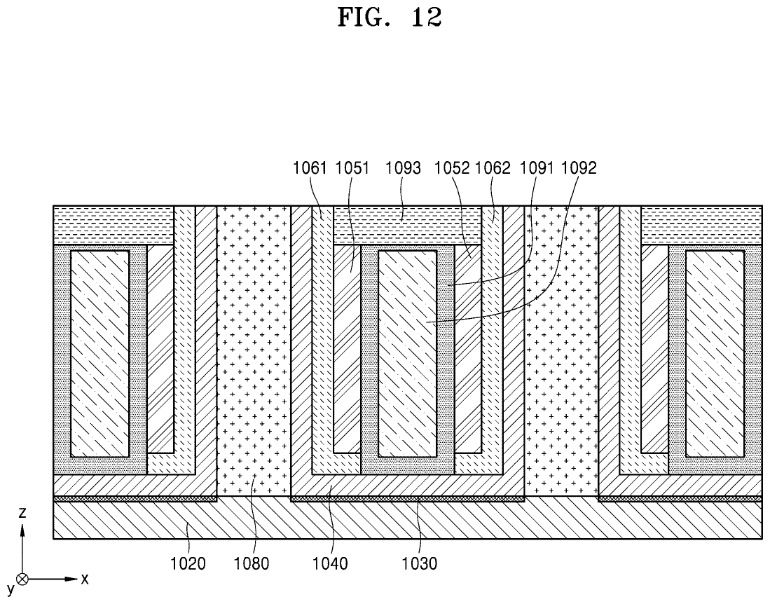

Referring to FIG. 12, an insulating liner 1091 may be deposited from a lower surface of the channel 1040 and may be stacked to an upper surface level of the first gate electrode 1051 and/or the second gate electrode 1052. An upper insulating layer 1093 may be deposited on the upper surface of the first gate electrode 1051 and/or the second gate electrode 1052 and an upper surface of the insulating liner 1091. The upper insulating liner 1091 and a buried insulating layer 1092 may not be distinguished. A surface level of the upper insulating layer 1093 may coincide with the upper surface of the mold insulating material 1080, the upper surfaces of the first vertical extension portion 1041 and the second vertical extension portion 1042, the upper surfaces of the first gate electrode 1051 and the second gate electrode 1052, and the upper surface levels of the first gate insulating layer 1061 and the second gate insulating layer 1062.

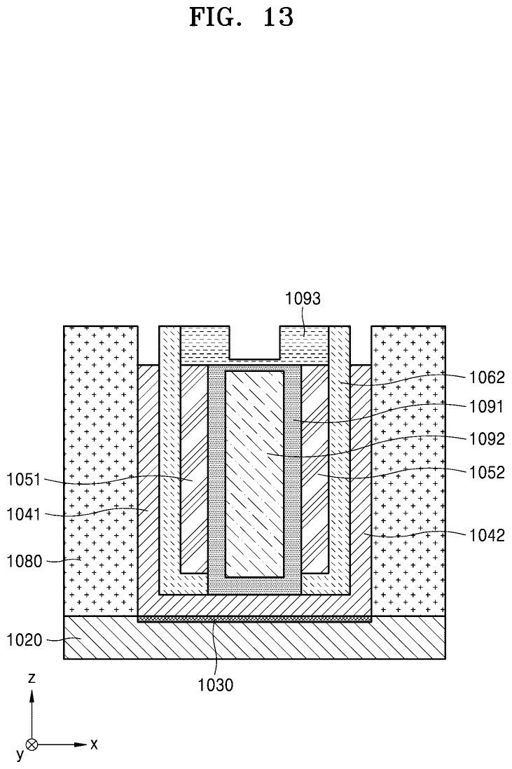

Referring to FIG. 13, upper portions of the first vertical extension portion 1041 and the second vertical extension portion 1042 may be etched.

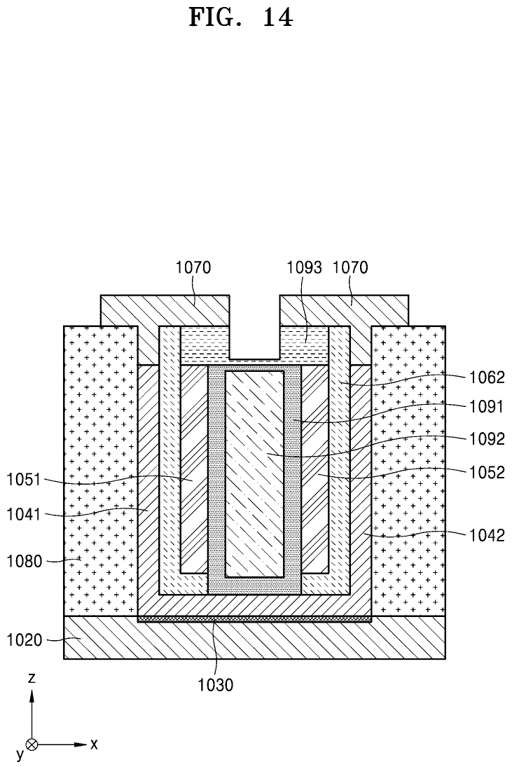

Referring to FIG. 14, an upper electrode 1070 may be deposited on the upper portions of the first vertical extension portion 1041 and the second vertical extension portion 1042. After depositing the upper electrode 1070, a central portion of the upper electrode 1070 and an upper portion of the upper insulating layer 1093 may be partially etched.

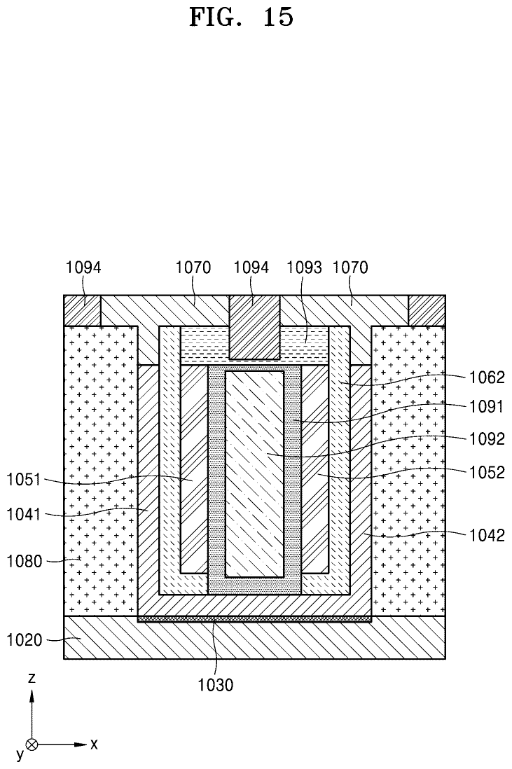

Referring to FIG. 15, an insulating layer 1094 may cover a space between the upper electrodes 1070 and the upper portion of the upper insulating layer 1093. An upper surface level of the insulating layer 1094 and a surface level of the upper electrode 1070 may be coincident.

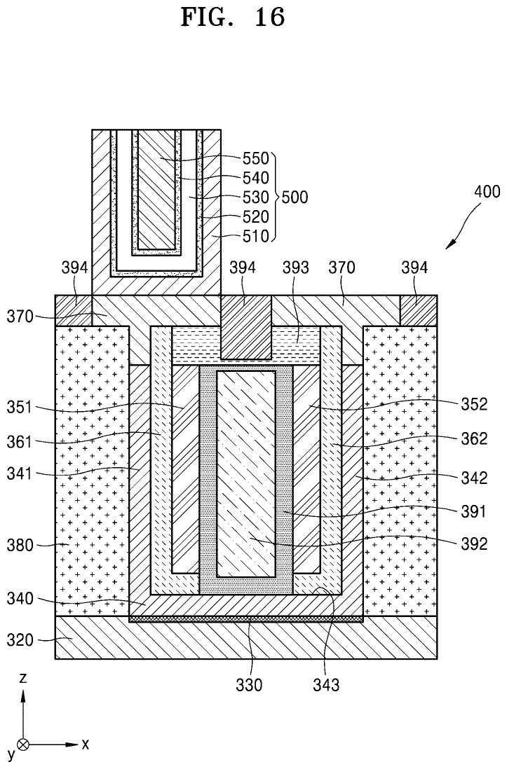

FIG. 16 illustrates an example in which the semiconductor devices 100, 200, and 300 according to embodiments is applied to a DRAM. For convenience, the semiconductor device 300 of FIG. 3 is described as an example, and because the semiconductor device included in the memory device 400 is the same as that described with reference to FIG. 3, a detailed description thereof is omitted for brevity.

Referring to FIG. 16, the memory device 400 may include a semiconductor device 300 and a capacitor 500 connected to an upper electrode 370 of the semiconductor device 300.

The capacitor 500 may include a first electrode 510, a dielectric film 530, and a second electrode 550. The dielectric film 530 may include at least one of, for example, HfO₂, ZrO₂, CeO₂, La₂O₃, Ta₂O₃, and TiO₂. A lower interface film 520 may further be provided between the first electrode 510 and the dielectric film 530. The lower interface film 520 may include a material represented by MM′ON, M′O or M′ON, wherein M includes one of Be, B, Na, Mg, Al, Si, K, Ca, Sc, Ti, V, Cr, Mn, Fe, Co, Ni, Cu, Zn, Ga, Ge, Rb, Sr, Y, Zr, Nb, Mo, Tc, Ru, Rh, Pd, Ag, Cd, In, Sn, Sb, Te, Cs, Ba, La, Ce, Pr, Nd, Pm, Sm, Eu, Gd, Tb, Dy, Ho, Er, Tm, Yb, Lu, Hf, Ta, W, Re, Os, Ir, Pt, Au, Hg, Tl, Pb, Bi, Po, Fr, Ra, Ac, Th, Pa, U, and wherein M′ includes one of H, Li, Be, B, N, O, Na, Mg, Al, Si, P, S, K, Ca, Sc, It may contain any one of Ti, V, Cr, Mn, Fe, Co, Ni, Cu, Zn, Ga, Ge, As, Se, Rb, Sr, Y, Zr, Nb, Mo, Tc, Ru, Rh, Pd, Ag, Cd, In, Sn, Sb, Te, Cs, Ba, La, Ce, Pr, Nd, Pm, Sm, Eu, Gd, Tb, Dy, Ho, Er, Tm, Yb, Lu, Hf, Ta, W, Re, Os, Ir, Pt, Au, Hg, Tl, Pb, Bi, Po, Fr, Ra, Ac, Th, Pa, U. A leakage current reduction film 540 may further be provided between the dielectric film 530 and the second electrode 550. The leakage current reduction film 540 may include, for example, an AlZrO film. However, the leakage current reduction film 540 is not limited thereto.

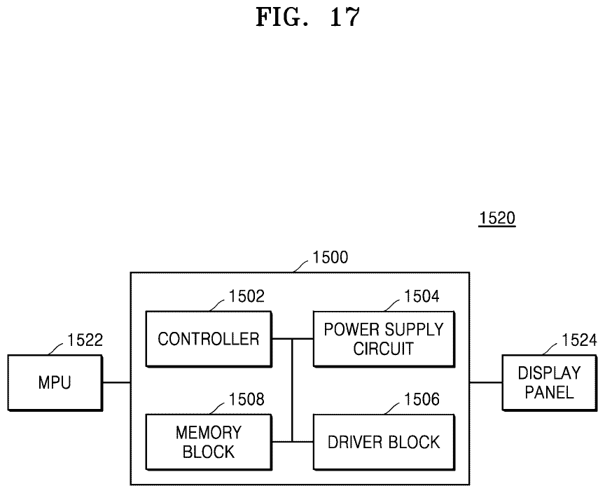

FIG. 17 is a schematic block diagram of a display driver IC (DDI) 1500 and a display device 1520 including the DDI 1500 according to an embodiment.

Referring to FIG. 17, the DDI 1500 may include a controller 1502, a power supply circuit 1504, a driver block 1506, and a memory block 1508. The control unit 1502 decodes a command received from the main processing unit (MPU) 1522 and controls each block of the DDI 1500 to implement an operation according to the command. The power supply circuit 1504 generates a driving voltage in response to the control by the control unit 1502. The driver block 1506 drives the display panel 1524 using the driving voltage generated by the power supply circuit 1504 in response to the control by the control unit 1502. The display panel 1524 may be a liquid crystal display panel or a micro-LED device. The memory block 1508 is a block that temporarily stores commands input to the control unit 1502 or control signals output from the control unit 1502, or stores necessary data, and may include a memory, such as a RAM or a ROM. The power supply circuit 1504 and the driver block 1506 may include semiconductor devices according to the embodiments described above with reference to FIGS. 1 to 15.

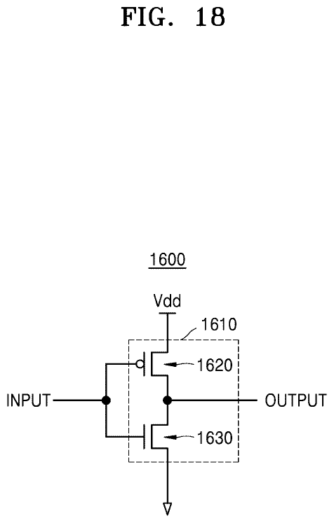

FIG. 18 is a circuit diagram of a CMOS inverter 1600 according to an embodiment.

Referring to FIG. 18, the CMOS inverter 1600 includes a CMOS transistor 1610. The CMOS transistor 1610 is composed of a PMOS transistor 1620 and an NMOS transistor 1630 connected between a power terminal Vdd and a ground terminal. The CMOS transistor 1610 may include a semiconductor device according to an embodiment described above with reference to FIGS. 1 to 15.

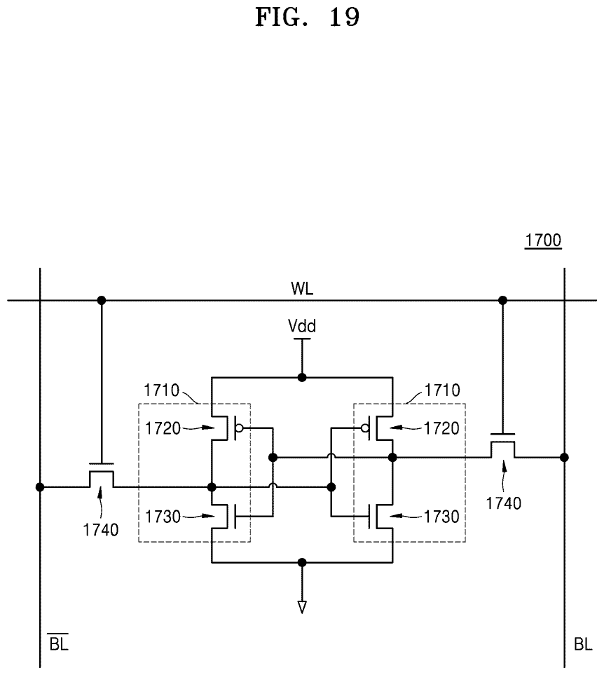

FIG. 19 is a circuit diagram of a CMOS SRAM device 1700 according to an embodiment.

Referring to FIG. 19, the CMOS SRAM device 1700 includes a pair of driving transistors 1710. The pair of driving transistors 1710 are each composed of a PMOS transistor 1720 and an NMOS transistor 1730 connected between a power terminal Vdd and a ground terminal. The CMOS SRAM device 1700 may further include a pair of transfer transistors 1740. A source of the transfer transistor 1740 is cross-connected to a common node of the PMOS transistor 1720 and the NMOS transistor 1730 constituting the driving transistor 1710. The source of the PMOS transistor 1720 is connected to the power terminal Vdd, and the source of the NMOS transistor 1730 is connected to the ground terminal. A word line WL may be connected to gates of the pair of transfer transistors 1740, and a bit line BL and an inverted bit line may be connected to the drains of each of the pair of transfer transistors 1740, respectively.

At least one of the driving transistor 1710 and the transmission transistor 1740 of the CMOS SRAM device 1700 may include a semiconductor device according to the embodiments described above with reference to FIGS. 1 to 15.

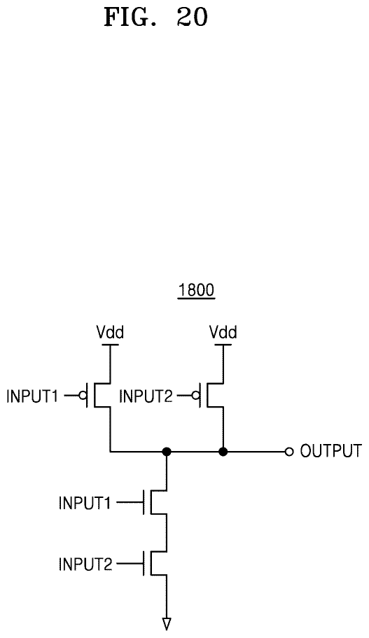

FIG. 20 is a circuit diagram of a CMOS NAND circuit 1800 according to an embodiment.

Referring to FIG. 20, the CMOS NAND circuit 1800 includes a pair of CMOS transistors to which different input signals are transmitted. The CMOS NAND circuit 1800 may include the semiconductor devices according to the embodiments described above with reference to FIGS. 1 to 15.

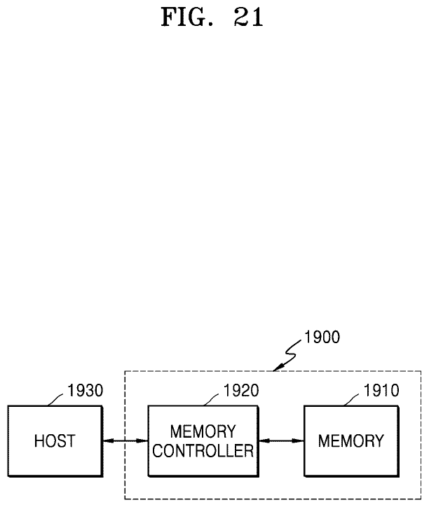

FIG. 21 is a block diagram illustrating an electronic system 1900 according to an embodiment.

Referring to FIG. 121, the electronic system 1900 includes a memory 1910 and a memory controller 1920. The memory controller 1920 may control the memory 1910 to read data from and/or write data to the memory 1910 in response to a request from the host 1930. At least one of the memory 1910 and the memory controller 1920 may include a semiconductor device according to the embodiments described above with reference to FIGS. 1 to 15.

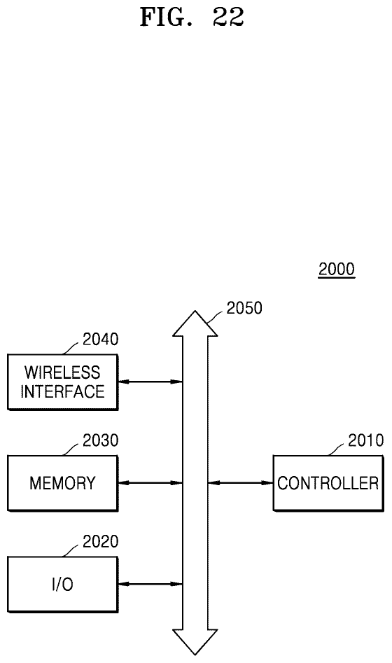

FIG. 22 is a block diagram of an electronic system 2000 according to an embodiment.

Referring to FIG. 22, the electronic system 2000 may configure a wireless communication device, or a device capable of transmitting and/or receiving information in a wireless environment. The electronic system 2000 includes a controller 2010, an input/output device (I/O) 2020, a memory 2030, and a wireless interface 2040, which are each interconnected via a bus 2050.

The controller 2010 may include at least one of a microprocessor, a digital signal processor, or a processing device similar thereto. The input/output device 2020 may include at least one of a keypad, a keyboard, or a display. The memory 2030 may be used to store commands executed by the controller 2010. For example, the memory 2030 may be used to store user data. The electronic system 2000 may utilize the wireless interface 2040 to transmit/receive data over a wireless communication network. The wireless interface 2040 may include an antenna and/or a wireless transceiver. The electronic system 1000 may include a semiconductor device according to the embodiments described above with reference to FIGS. 1 to 15.

The semiconductor device and the method of manufacturing the semiconductor device according to the embodiments may provide a semiconductor device including a doped region between a channel and a lower electrode.

The embodiments described above are examples, thus, it will be understood by those of ordinary skill in the art that various changes in form and details may be made therein without departing from the spirit and scope of the disclosure. Therefore, the true technical protection scope according to the embodiments should be determined by the technical ideas of the disclosure described in the following claims.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
a lower electrode;
a channel on the lower electrode;
a gate insulating layer on the channel;
a gate electrode on the gate insulating layer; and
an upper electrode on the gate electrode, wherein
the lower electrode includes a doped region,
the doped region includes at least one of indium (In) and niobium (Nb), and
the lower electrode, the channel, and the upper electrode are spaced apart from each other in a direction perpendicular to the lower electrode.

2. The semiconductor device of claim 1, wherein
the doped region is closer to the channel compared to a part of the lower electrode that does not include the doped region.

3. The semiconductor device of claim 1, wherein an atomic percentage of at least one of In and Nb in the doped region is 10 at % to 30 at %.

4. The semiconductor device of claim 1, wherein
the doped region includes a first portion and a second portion,
the first portion of the doped region is closer to the channel compared to the second portion of the doped region,
the second portion of the doped region is closer to a lower end of the lower electrode compared to first portion of doped region,
in the doped region, an atomic percentage of at least one of In and Nb is higher in the first portion of the doped region than in second portion of the doped region.

5. The semiconductor device of claim 1, wherein the channel includes a lower portion, a first vertical extension portion extending from a first end of the lower portion, and a second vertical extension portion extending from a second end of the lower portion.

6. The semiconductor device of claim 1, wherein the channel includes at least one of indium (In), zinc (Zn), tin (Sn), gallium (Ga), and hafnium (Hf).

7. The semiconductor device of claim 1, wherein the channel includes at least one of InGaZnO, ZnO, ZrInZnO, InZnO, InGaZnO₄, ZnSnO, In₂O₃, Ga₂O₃, HfInZnO, GaInZnO, HfO₂, SnO₂, WO₃, TiO₂, Ta₂O₅, In₂O₃SnO₂, MgZnO, ZnSnO₃, ZnSnO₄, CdZnO, CuAlO₂, CuGaO₂, Nb₂O₅, TiSrO₃, zinc indium oxide (ZIO), or indium gallium oxide (IGO).

8. The semiconductor device of claim 1, further comprising:
a mold insulating material, wherein
the channel is in the mold insulating material,
the doped region includes In,
the lower electrode includes tungsten (W), and
the mold insulating material includes silicon nitride (SIN).

9. The semiconductor device of claim 1, further comprising:
a mold insulating material, wherein
the channel is in the mold insulating material,
the doped region includes Nb,
the lower electrode includes titanium (Ti), and
the mold insulating material includes SiN.

10. The semiconductor device of claim 1, further comprising:
a mold insulating material,
the channel is in the mold insulating material,
a first end of the channel and a second end of the channel are in contact with the mold insulating material,
the first end of the channel and the second end of the channel are disposed in a direction parallel to the lower electrode, and
the doped region extends along the channel from the first end of the channel to the second end of the channel in the direction parallel to the lower electrode.

11. A method of manufacturing a semiconductor device, the method comprising:
forming an oxide layer on a lower electrode;
heat-treating the oxide layer to form a doped region on the lower electrode;
wet-etching and removing the oxide layer; and
forming a channel on the doped region, wherein
the oxide layer includes at least one of indium (In) and niobium (Nb), and
the doped region includes at least one of In and Nb.

12. The method of claim 11, wherein the doped region is closer to the channel compared to a part of the lower electrode that does not include the doped region.

13. The method of claim 11, wherein the heat-treating the oxide layer forms the doped region in a region having a certain height from an upper surface of the lower electrode in a direction perpendicular to the lower electrode.

14. The method of claim 11, wherein an atomic percentage of at least one of In and Nb in the doped region is 10 at % to 30 at %.

15. The method of claim 11, wherein
the doped region includes a first portion and a second portion,
the first portion of the doped region is closer to the channel compared to the second portion of the doped region,
the second portion of the doped region is closer to a lower end of the lower electrode compared to first portion of doped region, and
in the doped region, an atomic percentage of at least one of In and Nb is higher in the first portion of the doped region than in the second portion of the doped region.

16. The method of claim 11, wherein the channel includes at least one of In, zinc (Zn), tin (Sn), gallium (Ga), and hafnium (Hf).

17. The method of claim 11, wherein the channel includes at least one of InGaZnO, ZnO, ZrInZnO, InZnO, InGaZnO₄, ZnSnO, In₂O₃, Ga₂O₃, HfInZnO, GaInZnO, HfO₂, SnO₂, WO₃, TiO₂, Ta₂O₅, In₂O₃SnO₂, MgZnO, ZnSnO₃, ZnSnO₄, CdZnO, CuAlO₂, CuGaO₂, Nb₂O₅, TiSrO₃, zinc indium oxide (ZIO), or indium gallium oxide (IGO).

18. The method of claim 11, further comprising:
providing a mold insulating material on the lower electrode, wherein
the forming the channel on the doped region includes forming the channel in the mold insulating material,
the doped region includes In,
the lower electrode includes tungsten (W), and
the mold insulating material includes silicon nitride (SIN).

19. The method of claim 11, further comprising:
providing a mold insulating material on the lower electrode, wherein the forming the channel on the doped region includes forming the channel in the mold insulating material, the doped region includes Nb,
the lower electrode includes titanium (Ti), and
the mold insulating material includes SiN.

20. The method of claim 11, further comprising:
providing a mold insulating material on the lower electrode, wherein
the forming the channel on the doped region includes forming the channel in the mold insulating material such that a first end of the channel and a second end of the channel are in contact with the mold insulating material,
the first end of the channel and the second end of the channel are disposed in a direction parallel to the lower electrode, and
the doped region extends along the channel from the first end of the channel to the second end of the channel in the direction parallel to the lower electrode.
